(19) United States
(12) Patent Application Publication
(10) Pub. No.: US 2019/0304516 A1
(43) Pub. Date: Oct. 3, 2019

(54) APPARATUSES AND METHODS FOR COUPLING DATA LINES IN MEMORY DEVICES

(71) Applicant: Micron Technology, Inc., Boise, ID (US)

(72) Inventors: Hideo Shimizu, Sagamihara (JP); Makoto Kitayama, Hachioji (JP); Mototsugu Fujimitsu, Fuchu (JP)

(73) Assignee: Micron Technology, Inc., Boise, ID (US)

(21) Appl. No.: 15/938,965

(22) Filed: Mar. 28, 2018

(51) Int. Cl. G11C 7/10; G06F 11/10; G11C 29/52; G11C 7/06; G11C 8/10; G11C 29/42; G11C 5/06

(52) U.S. Cl. CPC G11C 7/109; G06F 11/1068; G11C 29/52; G11C 7/1063; G11C 5/06; G11C 8/10; G11C 29/42; G11C 7/1096; G11C 7/06

(57) ABSTRACT

Apparatuses and methods for coupling data lines in a memory device are disclosed. An example apparatus includes first and second local IO lines, first and second global IO lines, and a control circuit. The control circuit is configured in a write operation to bring the first local IO line and the first global IO line to one of first and second combinations in logic level and the second local IO line and the second global IO line to the other of the first and second combinations in logic level, and further configured in a read operation to cause the first local IO line and the first global IO line into to one of third and fourth combinations in logic level and the second local IO line and the second global IO line to the other of the third and fourth combinations in logic level.

### BACKGROUND

Memory devices are widely used to store information in various electronic devices such as computers, wireless communication devices, cameras, digital displays, and the like. Information is stored by programing different states of a memory device. For example, binary devices have two states, often denoted by a logic “1” or a logic “0.” In other systems, more than two states may be stored. To access the stored information, the electronic device may read, or sense, the stored information in the memory device. To store information, the electronic device may write, or program, the state in the memory device.

Various types of memory devices exist, including random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, and others. Memory devices may be volatile or non-volatile. Non-volatile memory, e.g., flash memory, can store data for extended periods of time even in the absence of an external power source. Volatile memory devices, e.g., DRAM, may lose their stored state over time unless they are periodically refreshed by an external power source. A binary memory device may, for example, include a charged or discharged capacitor.

A memory device may include hierarchical data lines that may be pre-charged in some instances. In a typical memory operation, a pre-charge operation may be executed within the time frame specified by memory timing requirements. A read-modify-write (RMW) operation, by way of contrast, includes multiple stages that may prevent a pre-charge operation from being executed within specified memory timing requirements. More specifically, a RMW operation includes a read operation and a write operation, both of which have to be executed within the specified timing. Because both operations cause an increased amount of current to flow, it may not be possible to pre-charge the hierarchical data lines, and, at the same time, meet the specified timing requirements. Thus, in order to meet the timing requirements, some memory devices perform read and write operations without pre-charging the hierarchical data lines during a RMW operation.

Even with a pre-charging operation omitted for a read-modify-write operation, problems may still arise with meeting timing requirements. For example, when a pre-charging operation is omitted, read data may be present on the hierarchical data lines. When write data calls for an inversion of a particular bit of read data, lines capacitances or other circuit elements may impede a fast transition of the data line.

Accordingly, there is a need in the art for fast data line transitions. These and other issues are addressed in following disclosure.

### BRIEF DESCRIPTION OF THE DRAWINGS

FIG. 1 is a schematic illustration of a portion of a memory according to an embodiment of the present disclosure.

FIG. 2 is a schematic diagram that illustrates an example layout for a semiconductor memory device in accordance with the present disclosure.

FIG. 3 is a schematic diagram that illustrates a portion of a semiconductor device that includes a sub-amplifier in accordance with the present disclosure.

FIGS. 4A and 4B are timing diagrams that show data and control signals associated with a read-modify-write operation in accordance with the present disclosure.

FIG. 5 is a schematic illustration of a memory that may be configured for a dedicated error correcting code operation.

FIG. 6A is a schematic illustration of a portion of a write driver of a memory device in accordance with the present disclosure.

FIG. 6B is a schematic illustration of a portion of a main amplifier of a memory device in accordance with the present disclosure.

### DETAILED DESCRIPTION

A semiconductor memory device in accordance with the present disclosure may include connections between hierarchical data lines that facilitate faster write times. Connections between hierarchical data lines in accordance with the present disclosure may be reversed at a point where lower level hierarchical data lines intersect with higher level hierarchical data lines. This intersection may occur at a sub-amplifier that is arranged between one or more sense amplifiers and a main amplifier. The sub-amplifier may be generally configured to transfer data between the lower level hierarchical data lines coupled to the sense amplifiers and the higher level hierarchical data lines coupled to the main amplifier. The sub-amplifier may include a transfer gate that facilitates transfer of write data from the higher level hierarchical data lines to the lower level hierarchical data lines. In accordance with the present disclosure, the hierarchical data lines may be reversed connected at this transfer gate. More specifically, the transfer gate may couple a “true” differential data line on the higher hierarchical data line side to a “bar” differential data line on the lower hierarchical data line side. Similarly, the transfer gate may couple a “bar” differential data line on the higher hierarchical data line side to a “true” differential data line on the lower hierarchical data line side.

This reversed connection between the hierarchical data lines may facilitate faster write times in write operations such as a read-modify-write where read data may be present on the hierarchical data lines at write time. Read data may present because a pre-charging operation is omitted in order to meet timing requirements. The read-modify-write operation may operate on a particular unit of memory such as “byte” or “word” that includes a plurality of bits. Each bit is either modified or not modified by the read-modify-write operation. For a bit that is modified, the read data present on the hierarchical data lines is inverted such that the data flips from “one” to “zero” or from “zero” to “one.” For a bit that is not modified, the read data present on the hierarchical data lines remains unchanged as data is written back to memory. Faster write times may be achieved because the reversed connection between the hierarchical data lines results in an inversion of the lower level hierarchical data lines that begins at a time before the memory device finishes calculating the write data. In the event that the write data indicates that a particular bit is to be modified, the inversion of the lower level hierarchical data line is accelerated at write time, in the event that the write data indicates that a particular bit is not to be modified, the inversion of the lower level hierarchical data line is reversed at write time.

A semiconductor memory device in accordance with the present disclosure may include an error correcting code functionality that is configured to correct certain errors that may be detected in stored data. A memory may be configured with a dedicated error correcting code operation in some embodiments. Here, the memory may include a stored parity bit that is associated with each byte or other unit of stored data. This parity bit may be read from memory along with the associated data byte at read time. In other embodiments, a parity bit may be calculated at read time rather than being stored in a dedicated parity bit location in memory. In either case, the memory device may use a read-modify-write operation in implementing the error correcting code functionality. Here, the memory device may execute a read-modify-write operation where write data is calculated in a parity operation that is based on read data and the parity bit. A semiconductor memory device having an error correcting code functionality may include a reversed connection between a hierarchical data lines in order to facilitate faster read-modify-write times and thus faster error correction code times. A semiconductor memory device having a reversed data connection in accordance with the present disclosure may also include circuits that are configured to prevent data errors from occurring a write operation includes masked data.

### Overview of Memory Architecture

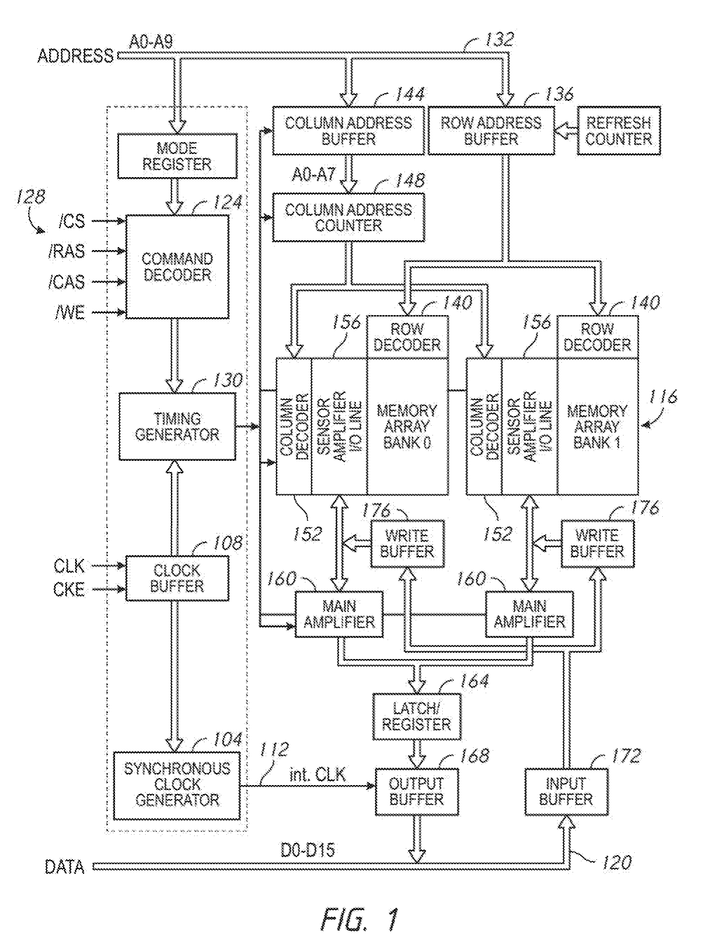

FIG. 1 is a schematic illustration of a portion of a memory 100 according, to an embodiment of the present disclosure. The memory 100 includes an array 116 of memory cells, which may be, for example, DRAM memory cells, SRAM memory cells, flash memory cells, or some other type of memory cells. The memory 100 may be generally configured to operate in cooperation with a larger digital system that includes at least a processor configured to communicate with the memory 100. In the present description, “external” refers to signals and operations outside of the memory 100, and “internal” refers to signals and operations within the memory 100. As an illustrative example, the memory 100 may be coupled to a microprocessor that provides external commands and clock signals to the memory 100. Although examples in the present description are directed to synchronous memory devices, the principles described herein are equally applicable to other types of synchronous integrated circuits.

The memory 100 may be generally configured to execute read and/or write commands received from an external device. The timing of signals external to the memory 100 may be determined by the external clock signal CLK. Operations within the memory 100 are typically synchronized to external operations. A synchronous clock generator 104 is generally configured to receive the external clock signal CLK through a clock buffer 108 and to generate a synchronized internal clock signal 112. The synchronized internal clock signal 112 generated by the synchronous clock generator 104 may be provided to various internal memory components in order to facilitate the latching of command, address, and data signals in accordance with the external clock CLK.

The read and/or write commands executed by the memory 100 are generally directed to accessing memory cells associated with a memory array 116. Read commands provide data stored in the array 116 to the external device across a data bus 120. Write commands receive data from the external device across the data bus 120 and store the data in the memory array 116. In the read command example, data output may be placed on the data bus 120 of the memory 100 in synchronism with the external clock signal CLK so that the memory device 100 outputs data in a manner that allows the data to be captured by the external controller. To output data with proper timing, the synchronous clock generator 104 develops an internal clock signal in response to the external clock signal and applies the internal clock signal to latches contained in the memory device 100 to clock data. The internal clock signal and external clock CLK are synchronized to ensure the internal clock signal clocks the latches at the proper times to successfully capture the commands.

The memory system 100 includes a command decoder 124 that receives memory commands through a command bus 128. The command decoder 124 receives memory commands applied to the command bus 128, decodes the commands, and provides the decoded commands to a timing generator 130. The timing generator 130 generates corresponding control signal to perform various operations on the memory array 116. For example, the timing generator 130 may generate internal control signals to read data from and/or write data to the memory array 116. Row and column address signals associated with a particular command are applied to the memory 100 through an address bus 132. The address bus 132 provides a row address signal to a row address buffer 136, which provides output to one or more row decoders 140. The address bus 132 additionally provides a column address signal through a column address buffer 144 to a column address counter 148, which, provides output to one or more column decoders 152.

As can be seen in FIG. 1, row and column addresses may be provided by be address buffers 136, 144 to one or more row decoders 140 and one or more column decoders 152, respectively. The column decoders 152 select bit lines extending through the array 116 corresponding to respective column addresses. The row decoder 140 includes or is coupled to a word line driver or similar component that activates respective rows of memory cells in the array 116 corresponding to received row addresses. The selected data line (e.g., a bit line or bit lines) corresponding to a received column address are coupled to read/write circuitry that includes sense amplifier 156 circuits that are configured to amplify data stored in the various memory cells of the array 116. The sense amplifier 156 circuits are coupled main amplifiers 160, which are configured to further amplify data read from the array 116. A latch/register 164 captures the read data from the main amplifier 160 and provides the captured read data to an output buffer 168. The output buffer 168 then provides the read data to the data bus 120 for transmission out of the memory 100.

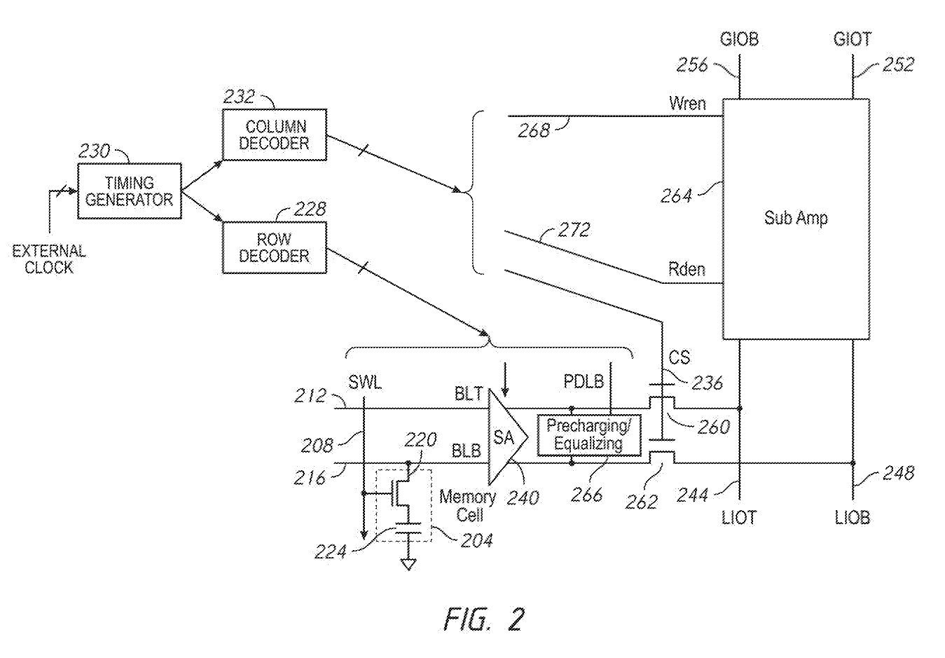

The data bus 120 may additionally be coupled to an input buffer 172 that is configured to receive write data that is, transmitted from an external source to the data bus 120. The input buffer 172 is coupled to write buffers 176 that are configured to receive the write data from the input buffer 172 and to transfer the write data to the memory array 116. The write buffer 176 may be additionally configured to write, data that is read from the memory array 116 back to the memory array 116. One example of this type of memory write-back is a read-modify-write operation that includes reading a data bit, modifying the data bit, and writing the modified data bit back to the same location in the memory array 116. This read-modify-write operation may occur in response to a “masked write” command in which data to be written is supplied to the memory system with mask data designating memory cell or cells that are released from being written with new data. The read-modify-write operation may also occur responsive to an ECC (error correction code) operation in which one or more parity bits are required to be corrected based on the calculation on data read out from accessed memory cells. In connection with a read-modify-write operation or other write-back memory, operations, the write buffer 176 may be configured to receive data via the main amplifiers 160. These and other features of an example memory data path are discussed in greater detail in connection with FIG. 2.

FIG. 2 is a schematic diagram that illustrates an example layout for a semiconductor memory device 200 in accordance with the present disclosure. The semiconductor device 200 of FIG. 2 may correspond to the memory device of FIG. 1. Certain components that are illustrated in FIG. 1 are omitted from FIG. 2 in order to simplify the drawing. FIG. 2 generally illustrates a data path that provides for transfer of data into and out of an individual memory cell 204. The memory cell 204 may be one of a plurality of memory cells that are arranged in a grid pattern (i.e., in matrix including a plurality of rows and a plurality of columns) within a memory array 116 (FIG. 1). A given memory cell 204 may be arranged at respective intersections of one or more sub-word lines (SWL) 208 and one or more bit lines (BL). Bit lines that may be coupled to a memory cell 204 include bit line (BLT) 212 and bit line bar (BLB) 216. A memory cell 204 may have a configuration in which a cell (or access) transistor 220 and a cell (or storage) capacitor 224 are connected in series between a corresponding one of the bit lines 212, 216 and a plate wiring supplied with a reference voltage. The cell transistor may include an n-channel MOS transistor, and a gate electrode thereof may be connected to a corresponding one of the sub-word lines 208.

The semiconductor device 200 of FIG. 2 includes a row decoder 228 that selects word lines corresponding to respective row addresses. The row decoder 228 may correspond to the row decoder 140 of FIG. 1. The row decoder 228 is a circuit that drives a plurality of word lines to select particular memory cells based on a row address. Based on signal from a timing generator 230, the row decoder 228 may be configured to drive one or more main word lines to which row decoders 228 may be directly coupled. Although not specifically shown in FIG. 2, the various main word lines may be coupled to sub-word lines (SWL) 208. This coupling may occur through various components that connect the main word lines to the sub-word lines SWL. For purposes of illustration, one sub-word line SWL is shown in FIG. 2. A sub-word line SWL may be driven by a sub-word driver (not shown). Each of the sub-word drivers drives a corresponding one of the sub-word lines 208 according to the row address. The row address is provided by the row decoder 228, which drives the row address onto main word lines. The sub-word drivers provide a coupling between the main word lines and the sub-word lines and in so doing drive sub-word lines 208 with appropriate signals responsive to the row address provided by the row decoder 228.

The semiconductor device 200 of FIG. 2 may also include a column decoder 232 that selects bit lines corresponding to respective column addresses. The column decoder 232 may correspond to the column decoder 152 of FIG. 1. The column decoder 232 is a circuit that selects a plurality of sense amplifiers on the basis of the column address. The column decoder 232 is configured to select a given plurality of sense amplifiers by driving column select (CS) 236 lines. FIG. 2 includes one column select line (CS) 236 and one sense amplifier 240 by way of example and not limitation. The sense amplifier 240 may be coupled to the pair of bit lines BLT/B. The sense amplifier 240 may be configured to amplify a potential difference generated in the pair of the bit lines BLT/B. Read data amplified by the sense amplifier 240 may be transferred to true and complementary local input/output lines (LIOT) 244 and (LIOB) 248, and then further transferred to true and complementary global input/output lines (GIOT) 252 and (GIOB) 256.

The local input/output lines LIOT/B and the global input/output lines GIOT/B are hierarchically structured input/output lines. The local input/output lines LIOT/B are used for transferring read data out from a memory cell 204 and/or write data to the memory cell 204. The local input/output line LIOT/B may be differential data input/output lines for transferring read data and write data by using a pair of lines. The global input/output lines GIOT/B are used for transferring data between a main amplifier and downstream components such as a latch or output buffer (FIG. 1). The global input/output lines GIOT/B may also be differential data input/output lines for transferring read data and write data by using a pair of lines.

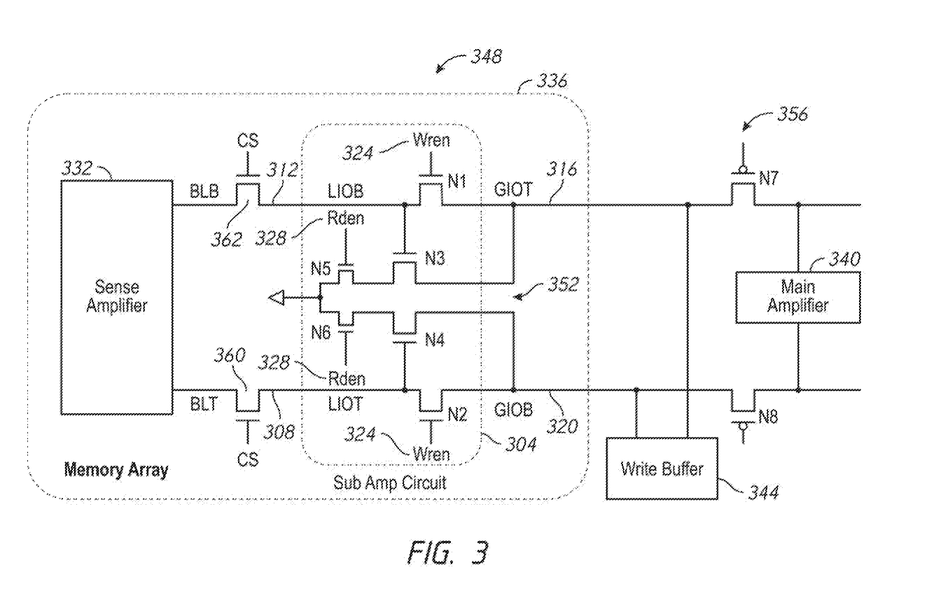

FIG. 2 illustrates various components that facilitate transfer of data between the memory cell 204 and the global input/output lines 252, 256. As mentioned, the sense amplifier 240 is coupled to the memory cell 204 via one or more bit line 212, 216. The sense amplifier 240 is configured to transfer data between the bit lines 212, 216 and the focal input/output lines 244, 248 via column switches 260 and 262, respectively. The, column switches 260, 262 may be driven by a column select CS line that enables a particular sense amplifier 240 to transfer its data onto the local input output lines 244, 248. The local input lines 244, 248 are received as inputs at a sub-amplifier 264. The sub-amplifier 264 may be generally configured to transfer data between the local input/output lines LIOT/B and the global input/output lines GIOT/B. The column decoder 232 may control this transfer of data through write enable (Wren) 268 and read enable (Rden) 272 signals that are generated by the column decoder 232 and received as other inputs at the sub-amplifier 264. Additional connections associated with sub-amplifier are shown in FIG. 3. The semiconductor device 200 of FIG. 2 may further include a precharging and equalizing circuit 266 that is activated by an enable level of a precharge signal PDLB provided from the row decoder 228 to precharge and equalize the outputs of the sense amplifier 240 and the bit lines BLT/B to a predetermined voltage level. Although not shown in FIG. 2, the memory device 200 further includes a precharging circuit that is configured to precharge the local input/output lines LIOT/B and the main input/output line GIOB/L to a high level (VDD), for example.

FIG. 3 is a schematic diagram that illustrates a portion of a semiconductor device that includes a sub-amplifier 304 in accordance with the present disclosure. FIG. 3 illustrates internal components of the sub-amplifier 304, as well as coupling between the sub-amplifier 304 and other components that are proximate to the sub-amplifier 304. The sub-amplifier 304 of FIG. 3 may correspond to the sub-amplifier 264 of FIG. 2. Thus, the sub-amplifier 304 may be generally configured to transfer data between the local input/output lines (LIOT) 308 and (LIOB) 312 and the global input/output lines (GIOT) 316 and (GIOB) 320. A column decoder (such as column decoder 232 of FIG. 2) may control this transfer of data through write enable (Wren) 324 and read enable (Rden) 328 signals that are generated by the column decoder and received as inputs at the sub-amplifier 304. A column decoder is illustrated in FIG. 2, but omitted from FIG. 3 in order to simplify the drawings. The precharging and equalizing circuit 266 of FIG. 2 is also omitted from FIG. 3 for the same reason.

The sub-amplifier 304 may be coupled to sense amplifiers 332 via the local input-output lines LIOT/B and column switches CS, such as is also shown in FIG. 2. FIG. 3 illustrates one sense amplifier 332 by way of example and not limitation. As indicated in FIG. 3, the sub-amplifier 304 and the sense amplifier 332 may be components of a memory array 336. FIG. 3 additionally illustrates that the sub-amplifier 304 may be coupled to a main amplifier 340 via the global input/output limes GIOT/B and transistors N7 and N8 and further to a write buffer 344 via the global input/output limes GIOT/B. Each of the transistors N7 and N8 may be of a P-channel type. The main amplifier 340 and the write buffer 344 may correspond respectively to the main amplifier 160 and the write buffer 176 of FIG. 1. Thus, the main amplifier 340 may be configured to receive data from the sub-amplifier 304 and to further amplify the data for transmission to downstream components that provide for transmission of the data to an external source.

The write buffer 344 may in one respect be configured to receive write data from the downstream components and to transfer the write data to the sub-amplifier 304. The write data may pass from the sub-amplifier 304 to the sense amplifier 332 and from there to a particular memory cell as described in connection with FIG. 2. As mentioned, a write buffer 344 may in another respect be configured to write data that is read from memory back to the same memory through memory write-back operations, one example of which is a read-modify-write operation. Here, a data bit is read to the write buffer 344 where it is modified as needed and written back to the same memory. In connection with a read-modify-write operation or other write-back memory operation, the write buffer 344 may be configured to receive data from the global input/output lines GIOT/B that otherwise couple the sub-amplifier 304 to the main amplifier 340.

The sub-amplifier 304 includes transistors N1 and N2 that together form a transfer gate 348 arranged at the intersection between the local input/output lines LIOT/B and the global input/output lines GIOT/B. The N1 transistor may be coupled between the true global input/output line GIOT and the complementary local input/output line LIOB, and the N2 transistor may be coupled between the complementary global input/output line GIOB and the true local input/output line LIOT. The N1 and N2 transistors may be nMOS (n-channel MOS) transistors in one embodiment. Conduction and non-conduction of the transistors N1 and N2 of the transfer gate 348 within the sub-amplifier 304 may be controlled based upon the Wren signal.

The sub-amplifier 304 including the transfer gate 348 may operate in both read mode and write mode. Read mode corresponds to a state in which information is read from a memory cell and output externally. Write mode corresponds to a state in which external information is written to a memory cell. Both the read mode and the write mode may be referred to herein as “active modes” that correspond to states in which the semiconductor device is accessed externally. The read-modify-write operation may be also included in the active modes. On the other hand, a state in which the semiconductor device is not accessed externally may be referred to herein as a “standby mode”. In connection with these active modes, the transfer gate 348 may be controlled by the write enable signal Wren. As shown in FIG. 3, the write enable signal Wren may be received as input at the gate terminals of the respective transistors N1 and N2 of the transfer gate 348.

The sub-amplifier 304 additionally includes transistors N3 to N6 that together form a read amplifier 352 arranged at the intersection between the local input/output lines LIOT/B and the global input/output lines GIOT/B. The read amplifier 352 may be formed as a single-ended amplifier that includes a first set of transistors N3 and N4 coupled at gates terminals thereof to the local input/output lines LIOB/T, respectively. The transistor N5 may be coupled between the transistor N3 and a power supply line such as ground (or Vss), and the transistor N6 may be coupled between the transistor N4 and the power supply line, the gates of the transistors N5 and N6 being supplied in common with the Rden signal. In this configuration, when the read amplifier 352 is activated by an enable level of the Rden signal, the true and complementary global lines GIOT and GIOB are driven responsive to potentials on the complementary and true local input/output lines LIOB and LIOT, respectively. Further, a load of the global input/output lines GIOT/B is not directly seen by the local input/output lines LIOT/B due to the transistors N1 to N4 so as to alleviate a driving load of the sense amplifier 332 connected to the bit lines BLT/B that drive the local input/output lines LIOT/B via the column switches (CS) 360, 362. By virtue of such an arrangement, the local input/output lines LIOT/B can be driven at high speed by the sense amplifier 332 during a read operation. Furthermore, the global input/output lines GIOT/B can be driven at high speed by adopting an arrangement in which the read amplifier is made a single-ended amplifier and the global input/output lines GIOT/B are driven with a high amplification factor, it is to be noted that the transistors N5 and N6 may be replaced with a single transistor that is controlled by the Rden signal. In this case, the sources of the transistors N3 and N4 may be coupled in common to a circuit node, and this circuit node may be coupled to the power supply line via such single transistor.

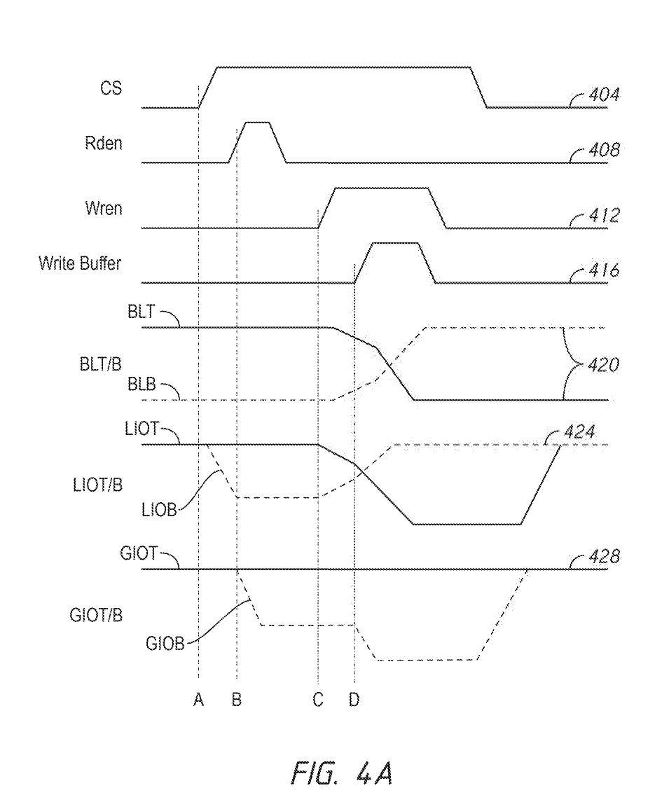

The connection between the global input/output lines GIOT/B and the local input/output lines LIOT/B may be controlled by the transistors N1 and N2 that together form the transfer gate 348. During read operations, the Rden signal is asserted so as to allow the read amplifier 352 to drive the GIOT/B lines responsive to the read data on the local input/output lines LIOT/B. The Wren signal may be de-asserted at this time. During write operations, the Wren signal is asserted so as to couple the GIOB/T lines to the LIOT/B lines together through the transfer gate 348. The read enable signal Rden may be de-asserted at this time. The assertion and de-assertion of Rden and Wren signals during the read-modify-write operations will describe below in detail with reference to FIG. 4A and FIG. 4B.

### Data Line Connections

A memory device in accordance with the present disclosure may include a reversed connection between the local input/output lines LIOT/B and the global input/output lines GIOT/B. Here, the LIOB line (complementary local input/output line) is coupled to the GIOT line (true global input/output line) via the transfer gate transistor N1, and the LIOT line (true local input/output line) is coupled to the GIOB line complementary global input/output line) via the transfer gate transistor N2. This is in contrast to a conventional arrangement where the LIOB line is coupled to the GIOB line, and the LIOT line is coupled to the GIOT line. In this configuration, the reversed connection between the LIOT/B and GIOT/B lines occurs through the transfer gate 348 during data write operation caused by a data write command or a read-modify-write command. In the read amplifier 352, on the other hand the transistor N3 may be connected such that it drives the true global input/output line GIOT responsive to the level on the complementary local input/output line LIOB and the transistor N4 is connected such that it drives the complementary global input/output line GIOB responsive to the level on the true local input/output lines LIOT. Accordingly, the read amplifier 352 is coupled between the LIOT/B and GIOT/B lines in a non-reversed manner. This is also in contrast conventional arrangement.

The sub-amplifier 304 thus configured with the reversed connection shown in FIG. 3 transfers data in a non-reversed manner during a read operation and in a reversed manner during a write operation. In a read operation, the read amplifier 352 transfers matching data from the local input/output lines LIOT/B to the global input/output lines GIOT/B. For example, the read amplifier 352 transfers a logical “one,” represented by a high voltage on the LIOT line and a low voltage on the LIOB line, to the global input/output lines as a logical “one,” represented by a high voltage on the GIOT line and a low voltage on the GIOB line. By way of contrast, in a write operation, the transfer gate 348 transfers opposite data from the global input/output lines GIOT/B to the local input/output lines LIOT/B. For example, the transfer gate 348 transfers a logical “one,” represented by a high voltage on the GIOT line and a low voltage on the GIOB line, to the local input/output lines as a logical “zero,” represented by a low voltage on the LIOT line and a high voltage on the LIOB line.

Given that the sub-amplifier 304 transfers data in a reversed manner during a write operation, the write buffer 344 may be configured to drive the global input/output lines GIOT/B with opposite data so that the correct data is ultimately written to memory. For example, in the event that a logical “one” is to be written to given memory cell, the write buffer may drive the GIOT/B lines with a logical “zero,” represented by a low voltage on the GIOT line and a high voltage on the GIOB line. The transfer gate 348 then transfers opposite data from the global input/output lines GIOT/B to the local input/output lines LIOT/B. Specifically, the transfer gate 348 transfers the logical “zero” on the GIOT/B lines to the local input/output lines as a logical “one,” represented by a high voltage on the LIOT line and a low voltage on the LIOB line. This logical “one” is then transferred to the bit lines BLT/B via the column switches 360 and 362 and the sense amplifier 332 for storage in the appropriate memory cell.

### Faster Write Times

A reversed connection in accordance with the present disclosure between the local input/output lines LIOT/B and the global input/output lines GIOT/B reduces write times associated with a read-modify-write operation. This advantage stems from a utilization of the time between an assertion of the write enable Wren signal and the write buffer being turned on. In some instances, this may occur during a time when a parity operation is performed. Reduced write times occur particularly in the case of write data that is the inverse of read data present on the signal lines GIOT/B, LIOT/B, and BLT/B, as discussed in detail below with reference to FIGS. 4A and 4B.

FIGS. 4A and 4B are timing diagrams that show data and control signals associated with a read-modify-write operation in accordance with the present disclosure. In the read-modify-write-operation of FIG. 4A, a data bit is read from memory cell and inverse data is written back to the memory cell. In the read-modify-write-operation of FIG. 4B, a data bit is read from memory cell and matching data is written back to the memory cell. FIGS. 4A and 4B include signal traces that correspond to data and control signal that are illustrated in FIG. 2 and FIG. 3.

FIGS. 4A and 4B include signal traces for the CS, Rden, and Wren control signals. The CS signal trace 404 may correspond to the column select signal CS that drives column switches 260 and 262 of FIGS. 2 (360 and 362 of FIG. 3) to enable a particular sense amplifier 240 to transfer its data to and from local input output lines LIOT/B. The Rden signal trace 408 may correspond to the read enable signal Rden that controls transfer of read data from the local input/output lines LIOT/B to the global input/output lines GIOT/B through the read amplifier 352. The Wren signal trace 412 may correspond to the write enable signal Wren that controls transfer write data from the global input/output lines GIOT/B to the local input/output lines LIOT/B through the transfer gate 348. FIGS. 4A and 4B additionally include a write buffer signal 416 that is asserted when the write buffer 344 is in an “on” (activated) state, and de-asserted when the write buffer 344 is in an “off” (deactivated) state.

FIGS. 4A and 4B include signal traces for the BLT/B, LIOT/B, and GIOT/B data signals. The BLT/B signal traces 420 may correspond to the differential bit line signals BLT/B that transfer data in and out of a memory cell through the operation of a sense amplifier. The LIOT/B signal traces 424 may correspond to the differential local input/output line signals LIOT/B that transfer data to and from the bit lines BLT/B. The GIOT/B signal traces 428 may correspond to the differential global input/output signals GIOT/B that transfer data to and from the local input/output lines LIOT/B.

Initially, at the beginning of a read-modify-write operation, the control signals CS, Rden, and Wren are at a low voltage indicating a de-asserted state. A differential voltage is present on the bit lines BLT/B. More specifically, one of the bit lines BLT/B (BLT in this example) is at a high voltage, while the other bit line BLT/B (BLB in this example) is at a low voltage level. The differential voltage present on the bit lines BLT/B may represent read data provided from a given memory cell of a memory array. With the column select CS line de-asserted, the local input/output lines LIOT/B are not driven to differing voltages. In this state, no particular data value is present on the local input/output lines LIOT/B so that both of the local input/output lines LIOT/B hold a precharge level (high level in this example) that was precharged prior to the assertion of the signal CS. Similarly, with the read enable Rden line de-asserted, the global input/output lines GIOT/B are not driven to differing voltages, resulting in that both of the global input/output lines GIOT/B hold a precharge level (high level in this example) that was precharged prior to the assertion of the signal CS. Thus, no particular data value is present on the global input/output lines GIOT/B.

At time point A, the column select signal CS is asserted. The column select signal CS drives column switches 260 and 262 of FIG. 2 (360 and 362 of FIG. 3) to enable the sense amplifier 332 to transfer read data from the bit lines BLT/B to the local input output lines LIOT/B. As shown in FIGS. 4A and 4B, the transfer of read data results in one of the local lines LIOT/B (LIOT in this example) keeping a high voltage, while the other local input/output line LIOT/B (LIOB in this example) is driven toward a low voltage level. The differential voltage present on the local input/output lines LIOT/B corresponds to the read data provided by the bit lines BLT/B.

At time point B, the read enable signal Rden is asserted. The asserted read enable Rden signal activates the read amplifier 352 so that the global input/output lines GIOT/B are driven responsive to the voltage levels on the local input/output lines LIOT/B. In response to the read enable Rden signal, cell data is read from the local input/output lines LIOT/B to the global input/output lines GIOT/B. As discussed previously and shown in FIGS. 4A and 4B, the activated read amplifier 352 transfers, the read data to the global input/output lines GIOT/B in a non-reversed manner, results in one of the global input/output lines GIOT/B (GIOT in this example) keeping a high voltage, while the other of the global input/output lines GIOT/B (GIOB in this example) is driven toward a low voltage level. The read enable signal Rden is thereafter de-asserted.

At time point C (i.e., after the read enable signal Rden has been de-asserted), the write enable signal Wren is asserted. The asserted write enable signal Wren drives the transfer gate 348 to couple the global input/output lines GIOT/B to the local input/output lines LIOT/B. As shown in FIGS. 4A and 4B, since the write buffer signal 416 is not yet asserted and holds the inactive low level and since the global input/output lines GIOT and GIOB are at high and low levels, respectively, the true local input/output line LIOT and the true bit line BLT are decreased a little bit in voltage level from the high level and the complementary local input/output line LIOB and the complementary bit line BLB are increased a little bit in voltage level from the low level. With the write enable signal Wren asserted, a data writeable state in the read-modify-write operation is initiated; however, the write buffer 344 is not yet enabled at this point because of the write buffer signal 416 being de-asserted. Accordingly, write data is not yet driven from the write buffer 344 onto the global input/output GIOT/B. During this time, write data may be calculated in the write buffer 344. When the read-modify-write operation is executed in connection with an error correcting code operation, the write buffer 344 may calculate write-back data that is to be written back to the same memory cell, based on a parity operation. When the read-modify-write operation is executed in connection with a masked write command accompanied with write data and mask data, write-back data may be obtained from the read data, the write data and the mask data.

At time point D, the write buffer signal 416 is asserted (changed to the active high level) while the write enable signal Wren is asserted to bring the write buffer 344 to an “on” (“activated”) state. The write buffer 344 may thus initiate a data write operation after waiting for a parity operation to end and write-back data to be determined. With this data write operation, the write buffer 344 drives the global input/output lines GIOT/B based on the write-back data to cause the local input/output lines LIOT/B and the bit lines BLT/B to be driven through the transfer gate 348.

As shown in FIGS. 4A and 4B, this data write operation is initiated, without pre-charging newly the BLT/B, LIOT/B and GIOT/B lines, from a state in which information read in the previous read operation is left in the bit lines BLT/B, the local input/output lines LIOT/B, and the global input/output lines GIOT/B. When the write-back data is inverse data to the read data, the write amplifier 344 drives the global lines GIOT/B without flipping their previous states in logic level, so that the signal lines LIOT/B and BLT/B are flipped in logic level from the previous state. This situation is illustrated in FIG. 4A. When the write-back data is the same as the read data, on the other hand, the write amplifier 344 drives the signal lines GIOT/B to flip their previous states in logic level, so that the signal lines LIOT/B, and BLT/B are not flipped in logic level from the previous states. This situation is illustrated in FIG. 4B.

A read-modify-write operation may operate on a particular unit of memory such as a “byte” or “word” that includes a plurality of bits. The timing diagrams of FIGS. 4A and 4B illustrate one bit of a read-modify-write operation by way of example and not limitation. Each bit in a read-modify-write is either modified (FIG. 4A) or not modified (FIG. 4B). For a bit that is modified or inverted, the read data present on the hierarchical data lines is inverted such that the data flips from “one” to “zero” or from “zero” to “one.” For a bit that is not modified, the read data present on the hierarchical data lines remains unchanged as data is written back to memory.

FIG. 4A illustrates the case where write-back data indicates that a particular bit is to be modified or inverted at write time. Thus, the read data present on the hierarchical data lines is inverted such that the data flips from “one” to “zero” or from “zero” to “one.” Once the write-back data is calculated, the write buffer 344 is turned-on (at time point D) and write-back data is driven onto the global input/output lines GIOT/B. In the example of FIG. 4A, the write-back data is “zero” that is inverse to the read data of “one”. As discussed previously, however, data is transferred from the GIOT/B lines to the LIOT/B lines in an inverse manner. Accordingly, the write buffer 344 is required to drive the GIOT/B lines with data “zero”, represented by a high level on the true global input/output line GIOT and a low level on the complementary global input/output line GIOB. This situation has already occurred on the GIOT/B lines by the read data, however. Thus, the write buffer 344 may drive the GIOT to high level and the GIOB line to a lower level with a small power and at a high speed. In response to this, the states in logic level of the local input/output lines LIOT/B and the bit lines BLT/B are flipped successively. In this way, the write-back data, that is inverse to the read data, is written back and stored in the appropriate memory cell from which the read data has been read out.

FIG. 4B illustrates the case where write-back data indicates that a particular bit is not to be modified at write time. Thus, the read data present on the hierarchical data lines is not inverted such that a “one” remains “one” and a “zero” remains a “zero.” Once the write-back data is calculated, the write buffer is turned-on (at time point D) and write-back data is driven onto the global input/output lines GIOT/B. In the example of FIG. 4B, the write-back data is “one” that is the same as the read data. Since data is transferred in an inverse manner from the GIOT/B lines to the LIOT/B lines, the write buffer 344 is required to drive the GIOT/B lines with data “zero”, represented by a low level on the true global input/output line GIOT and a high level on the complementary global input/output line GIOB. Accordingly, the write buffer 344 may drive the GIOT to a low level and the GIOB line to a high level to flip the states in logic level of the GIOT/B lines. Thus, the states in logic level of the LIOT/B lines and BLT/B lines are maintained. In this way, matching data is written back and stored in the appropriate memory cell from which the read data has been read out. While the GIOT/B lines are required to be flipped in logic level, the logic state of each of the LIOT/B and BLT/B lines is not required to be flipped, so that power consumption is suppressed.

In a conventional memory device in which each of read data and write-back data is transferred between the LIOT/B lines and the GIOT/B lines in a non-inverse manner, in order to write back data to the memory cell, that is inverse to the read data, all the GIOT/B, LIOT/B and BLT/B lines are required to flipped in logic level, so that large power is consumed with lower operation speed.

### Improved Error Correction

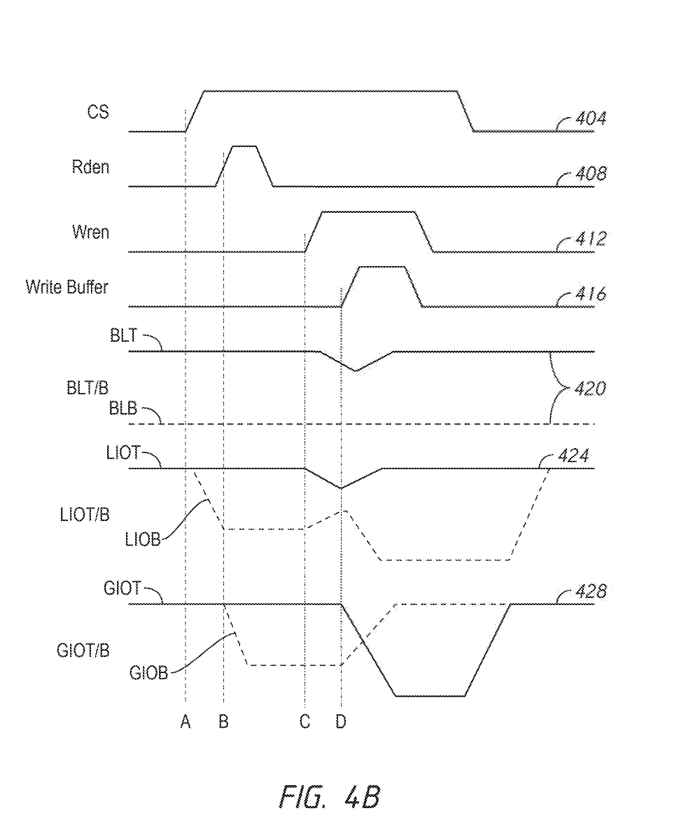

A semiconductor memory device in accordance with the present disclosure may include an error correcting code (ECC) functionality that is configured to correct certain errors that may be detected in stored data. FIG. 5 is a schematic illustration of a memory array 504 that may be configured for a dedicated error correcting code operation. The memory array 504 may include hierarchical data lines including local input/output lines (LIOT/B) 508 and global input/output lines (GIOT/B) 512. As described above, the memory array 504 may additionally include a reversed connection between hierarchical data lines in order to facilitate faster read-modify-write times and thus faster error correcting code times. Although not specifically shown in FIG. 5, the memory array 504 may additionally include bit lines BLT/B that are configured to transfer data between the local input/output lines LIOT/B and the various memory cells of the array 504. Coupling between the various hierarchical data lines may controlled by control components such as a column decoder (YDEC/MA) 516. A main amplifier 340 of FIG. 3 may be included in the YDEC/MA) 516. An error correcting code module 520 may control the ECC functionality that is implemented by the array 504. Certain other components that are part of or otherwise associated with the memory array 504, such as are illustrated in FIG. 1, are omitted from FIG. 5 in order to simplify the drawing. FIG. 5 includes one memory array 504 by way of example and not limitation.

FIG. 5 depicts an array 504 structure for an ECC-equipped memory device. Accordingly, the memory array 504 may include a data array 524 portion and a parity array 528 portion. The parity array 528 may be configured to store parity bits that are associated with data bytes or other units of data that are stored in the data array 524. The memory array 504 may be configured to read one or more parity bits from the parity array 528, along with a data byte from the data array 524 at read time. The memory array 504 may additionally be configured to handle a mask bit in connection with executing the dedicated error correcting code operation. Here, the memory array 504 generates parity data from data to be masked and write data. In order to generate the parity data from data to be masked, read data is read once from the memory array 504. In connection with this operation, the memory array 504 is configured to read array data once before writing, perform the error correcting code processing with that data and write data, generate parity data, and write the result. The memory array 504 may use a read-modify-write operation in implementing these error correcting code operations. The memory array 504 may execute the read-modify-write operation where write data is calculated in a parity operation that is based on read data and parity bit.

The array 504 may be associated with a memory device that is configured to execute a read-modify-write operation. The memory may use the read-modify-write operation in an error correcting code operation that includes masked and non-masked bits. The write-modify-write operation may be implemented differently for each of these types of bits. In a conventional processing of a masked bit, a write driver is typically stopped and data on the signal lines GIOT/B and LIOT/B is retained after the data is read from memory. For a bit that is not masked, data may be written from the write driver to cause the write data to be written to the appropriate memory cell. However, this conventional arrangement may be susceptible to static noise margin issues when used in a memory array in accordance with the present disclosure that includes a reversed connection between hierarchical data lines. Thus, as described in greater detail below, the memory array 504 may also include circuits that are configured to prevent data errors from occurring a write operation includes masked data.

Static noise margin issues in the array 504 may arise in connection with a write operation performed in connection with a masked bit. Because the bit to be masked is not written, the signal lines GIOT/B and LIOT/B retain data in a state of being read. Referring to the more detailed circuit diagram of FIG. 3, while the write driver 344 stops, the transistors N1 and N2 of the LIOT/B transfer gate 348 and the transistors N7 and N8 of the GIOT/B transfer gate 356 are both turned on. In this state, capacitive components of the global input/output lines GIOT/B, the local input/output lines LIOT/B, and the bit lines BLT/B are coupled together. As a result, electric charge from the global input/output lines GIOT/B and/or the local input/output lines LIOT/B may flow towards the memory array, causing the bit lines BLT/B to float. Depending on the floating voltage level of the bit lines BLT/B, there is a risk of an erroneous operation of the sense amplifier 332 that may result in loss of data.

In order to overcome these potential static noise margin issues, a memory device in accordance with the present disclosure may be configured to write back data that is masked in read operation. As mentioned, because parity data is generated from write data and read data as part of a read-modify-write operation, cell data is read out of the memory array in these operations. In accordance with present embodiments, a memory device may utilize that read data and rewrite the masked bit back to the memory array. Thus, after ECC correction of the relevant bit is performed, the corrected data may be rewritten to the memory array. Referring again to FIG. 3, data read from a memory cell may be rewritten at a write driver via the main amplifier 340.

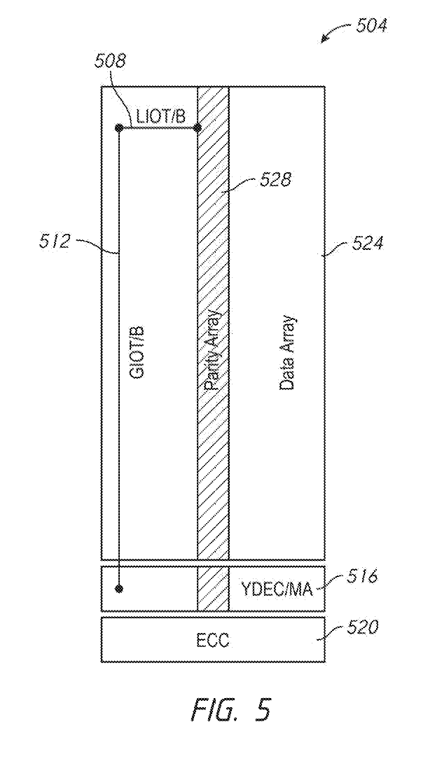

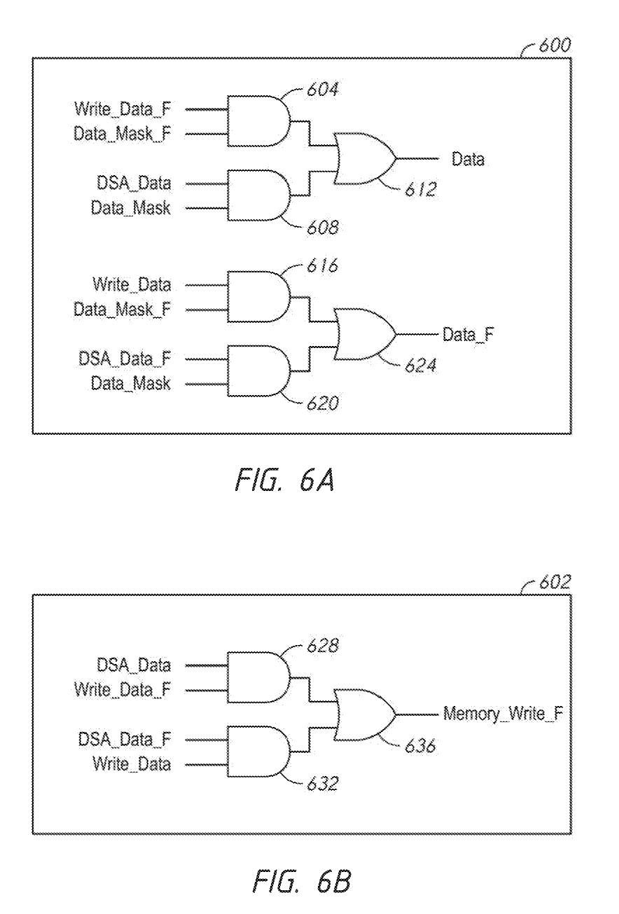

FIG. 6A is a schematic illustration of a portion of a write driver 600 of a memory device in accordance with the present disclosure. The write driver 600 may be configured to write back masked data that is read from memory as part of a parity operation. As described above, the parity operation may be executed in connection with an error correcting code operation that is executed in an ECC equipped semiconductor memory device in accordance with the present disclosure. The write driver 600 of FIG. 6A may be configured to drive the hierarchical data lines with read data for a portion of a data byte/word that is masked. For the portion of the data byte/word that is not masked, the write driver 600 drives the hierarchical data lines with write data. Thus, for a masked portion of an error correcting code operation, the write driver 600 rewrites data read from the memory for generating the parity data. With a memory device configured in this manner, the write driver 600 may operate without stopping operation for bits to be masked. Thus, the write driver 600 can be operated without stopping for each bit of an ECC operation. Therefore, the data errors that may be attributed to static noise margin issues can be reduced or eliminated.

The write driver 600 illustrated in FIG. 6A includes an output portion of one data line by way of example and not limitation. Other portions of the write driver 600 are omitted in order to simplify the drawing. An output portion of the write driver 600 data may include “true” and “bar” (or “complementary”) differential data lines that are labelled as “Data” and “Data_F” in FIG. 6A. A write bit, a read bit, and a mask bit provide input that drives the Data and Data_F lines The write bit is represented by differential signal lines that are labelled as “Write_Data” and “Write_Data_F” in FIG. 6A. “DSA_Data” and “DSA_Data_F” represent the differential signal lines for the read bit. “Mask_Data” and “Mask_Data_F” represent the differential signal lines f the mask bit.

The “true” side of the differential data line may include a first AND gate 604 and a second AND gate 608 that are each coupled to a first OR gate 612 that drives the Data line, Mask_Data_F may be provided as input to the first AND gate 604 and Mask_Data may be provided as input to the second AND gate 608. Write_Data_F provides the other input to the first AND gate 604 and DSA_Data provides the other input to the second AND gate 608. In this configuration, the first and second AND gates 604, 608 operate to select either the read data bit or the write data bit for the “true” side of the data line based on the mask data bit. More specifically, the mask bit is provided as either a “10” or “01” on the Mask_Data and Mask_Data_F lines and thus operates to select either the first or the second AND gate 604, 608 so as to pass either Write_Data_F or DSA_Data onto the Data line via the first OR gate 612.

The “bar” side of the differential data line may include a third AND gate 616 and a fourth AND gate 620 that are each coupled to a second OR gate 624 that drives the Data_F line. Mask_Data_F may be provided as input to the third AND gate 616 and Mask_Data may be provided as input to the fourth AND gate 620. Write_Data provides the other input to the third AND gate 616 and DSA_Data_F provides the other input to the fourth AND gate 620. In this configuration, the third and fourth AND gates 616, 620 operate to select either the read data bit or the write data bit for the “bar” side of the data line based on the mask data bit. More specifically, the mask bit, is provided as either a “10” or “01” on the Mask_Data and Mask_Data_F lines and thus operates to select either the third or the fourth AND gate 616, 620 so as to pass either Write_Data or DSA_Data_F onto the Data_F line via the second OR gate 624.

Thus, as illustrated by the one data line shown in FIG. 6A, the write driver 600 drives the hierarchical data lines with read data for masked bits. For bits that are not masked, the write driver 600 drives the hierarchical data lines with write data. A write driver 600 configured in this manner may operate without stopping operation for bits to be masked and thus may avoid data errors described above that may be attributed to static noise margin issues. It should be noted that the write drive 600 drives the hierarchical data lines with inverted data due to the reversed connection between the global input/output lines GIOT/B and the local input/output lines LIOT/B at the transfer gate 348.

As shown in FIG. 6A, the write driver 600 may be generally configured to write back read data for masked bits. However, in some cases it may be the case that a memory writes back an inverse of a read bit even though that read bit was masked in the memory operation. For example, when an error-correcting-code operation is executed, it may be the case that an error is detected in a masked bit. When such an error is detected, the read data for the masked bit may be inverted and then written back to memory. In accordance with present embodiments, a main amplifier component of a memory may include a detection circuit that is configured to determine when a data bit is to be written back to memory in this manner. An example of such a detection circuit is shown in FIG. 6B.

FIG. 6B is a schematic illustration of a portion of a main amplifier 602 of a memory device in accordance with the present disclosure. The main amplifier 602 may be configured to detect when an error is present in masked data such that an inverse of corresponding read data is written back to memory. The main amplifier 602 illustrated in FIG. 6B includes portions of a detection circuit by way of example and not limitation. Other portions of the main amplifier 602 are omitted in order to simplify the drawing. The detection circuit portion of a write driver 602 may include an output line, labelled as “Memory_Write_F” in FIG. 6B, that is asserted when a bit error is detected. A write bit and a read bit provide input that drives the output line Memory_Write_F. The write bit is represented by different signal lines that are labelled as “Write_Data” and “Write_Data_F” in FIG. 6B. “DSA_Data” and “DSA_Data_F” represent the differential signal lines for the read bit.

The detection circuit portion of a write driver 602 may include a fifth AND gate 628 and a sixth AND gate 632 that are each coupled to a third OR gate 636 that drives the output line Memory_Write_F. DSA_Data may be provided as input to the fifth AND gate 628 and DSA_Data_F may be provided as input to the sixth AND gate 632. Write_Data_F provides the other input to the fifth AND gate 628 and Write_Data provides the other input to the sixth AND gate 682. In this configuration, the fifth and sixth AND gates 628, 632 operate to compare read and write data for a masked bit to determine if an error is present. When such an error is present the detection circuit portion of the write driver 602 asserts the Memory_Write_F through the operation of the output line Memory_Write_F. An assertion of the output line Memory_Write_F may operate to write the inverse of read data back to the memory to thereby correct the detected error.

The above specification, examples and data provide a complete description of the structure and use of exemplary embodiments of the disclosure as defined in the claims. Although various embodiments of the disclosure have been described above with a certain degree of particularity, or with reference to one or more individual embodiments, those skilled in the art could make numerous alterations to the disclosed embodiments without departing from the spirit or scope of the disclosure. Other embodiments are therefore contemplated. It is intended that all matter contained in the above description and shown in the accompanying drawings shall be interpreted as illustrative only of particular embodiments and not limiting.

The foregoing description has broad application. The discussion of any embodiment is meant only to be explanatory and is not intended to suggest that the scope of the disclosure, including the claims, is limited to these examples. In other words, while illustrative embodiments of the disclosure have been described in detail herein, aspects of the disclosure may be otherwise variously embodied and employed, and the appended claims are intended to be construed to include such variations, except as limited by the prior art.

1-6. An apparatus comprising:
first and second local IO lines;
first and second global IO lines; and
a control circuit configured in a write operation to bring the first local IO line and the first global IO line to one of first and second combinations in logic level and the second local IO line and the second global IO line to the other of the first and second combinations in logic level, and further configured in a read operation to cause the first local IO line and the first global IO line into to one of third and fourth combinations in logic level and the second local IO line and the second global IO line to the other of the third and fourth combinations in logic level.

2. The apparatus of claim 1, wherein
the first combination in logic level includes a high logic value on the first local IO line and a high logic value on the first global IO line;
the second combination in logic level include a low logic value on the second local IO line and a low logic value on the second global IO line;
the third combination in logic level includes a high logic value on the first local IO line and a low logic value on the first global IO line; and
the fourth combination in logic level includes a low logic value on the second local IO line and a high logic value on the second global IO line.

3. The apparatus of claim 2, wherein
the read operation reads a data value of one; and
the write operation writes a data value of one.

4. The apparatus of claim 1, wherein
the first combination in logic level includes a low logic value on the second local IO line and a low logic value on the second global IO line;
the second combination in logic level include a high logic value on the first local IO line and a high logic value on the first global IO line;
the third combination in logic level includes a high logic value on the first local IO line and a low logic value on the first global IO line; and
the fourth combination in logic level includes a low logic value on the second local IO line and a high logic value on the second global IO line.

5. The apparatus of claim 4, wherein
the read operation reads a data value of zero; and
the write operation writes a data value of one.

6. The apparatus of claim 1, wherein
the first combination in logic level includes a low logic value on the first local IO line and a low logic value on the first global IO line;
the second combination in logic level include a high logic value on the second local IO line and a high logic value on the second global IO line;
the third combination in logic level includes a low logic value on the first local IO line and a high logic value on the first global IO line; and
the fourth combination in logic level includes a high logic value on the second local IO line and a low logic value on the second global IO line.

7. An apparatus comprising:
a first local IO line;
a second local IO line;
a first global IO line;
a second global IO line;
a first transistor coupled between the first local IO line and the first global IO line, the first transistor comprising a control node coupled to a first control line;
a second transistor coupled between the second local IO line and the second global IO line, the second transistor comprising a control node coupled to the first control line;
a third transistor comprising a control node coupled to the first local IO line;
a fourth transistor comprising a control node coupled to the second local IO line;
a fifth transistor comprising a control node coupled to a second control line; and
a sixth transistor comprising a control node coupled to the second control line;
wherein the third and fifth transistors are coupled in series between the first global IO line and a power supply line, and
wherein the fourth and sixth transistors are coupled in series between the second global IO line and the power supply line.

8. The apparatus of claim 7, wherein the first and second transistors are rendered conductive responsive, at least in part, to the first control line being set to an enable level, and the fifth and sixth transistors are rendered conductive responsive, at least in part, to the second control line being set to an enable level.

9. The apparatus of claim 8, wherein the first control line is set to the enable level by a write enable signal that is driven by a column decoder.

10. The apparatus of claim 8, where the second control line is set to the enable level by a read enable signal that is driven by a column decoder.

11. The apparatus of claim 7, further comprising:
a sense amplifier coupled to the first and second local IO lines;
a main amplifier coupled to the first and second global IO lines; and
a sub-amplifier arranged between the first and second local IO lines and the first and second global IO lines.

12. The apparatus of claim 11, wherein the sub-amplifier comprises a transfer gate that includes the first and second transistors.

13. The apparatus of claim 11, wherein the sub-amplifier includes a read amplifier that includes the third, fourth, fifth, and sixth transistors.

14. The apparatus of claim 7, further comprising a write driver that is configured to rewrite read data that is masked during a read-modify-write of an error correcting code operation.

15. The apparatus of claim 14, further comprising a main amplifier that is configured to invert the read data when the error correcting code operation indicates an error in the read data.

16-20. (canceled)

21. An apparatus comprising:
first and second data lines configured to form a first pair of true and complementary data lines;
third and fourth data lines configured to form a second pair of true and complementary data lines;
a first transistor coupled between the first and third data lines, the first transistor including a gate configured to receive a first control signal;
a second transistor coupled between the second and fourth data lines, the second transistor including a gate configured to receive the first control signal;
a third transistor coupled between the third data line and a first node, the third transistor including a gate coupled to the first data line;
a fourth transistor coupled between the fourth data line and a second node, the fourth transistor including a gate coupled to the second data line; and
a switch coupled between the first and second nodes and a power supply line and the switch supplied with a second control signal.

22. The apparatus of claim 21, wherein the switch comprises:
a fifth transistor coupled between the first node and the power supply line, the fifth transistor including a gate configured to receive the second control signal; and
a sixth transistor coupled between the second node and the power supply line, the sixth transistor including a gate configured to receive the second control signal.

23. The apparatus of claim 21, further comprising:
a sense amplifier coupled to the first and second data lines; and
a write butler coupled to the third and fourth data lines.

24. The apparatus of claim 23,
wherein when the second control signal takes an active level, one of the third and fourth transistors is rendered conductive and the other of the third and fourth transistors is rendered non-conductive; and
wherein when the first control signal takes an active level, both of the first and second transistors are rendered conductive.

25. The apparatus of claim 24, wherein in a read-modify-write operation the second control signal is configured to take the active level and the first control signal is configured to take the active level thereafter.
